(19) United States
(12) Patent Application Publication
(10) Pub. No.: US 2005/0233489 A1
(43) Pub. Date: Oct. 20, 2005

(54) Method for manufacturing electroluminescence display panel and evaporation mask

(76) Inventors: Ryuji Nishikawa, Gifu-shi (JP); Tsutomu Yamada, Motosu-gun (JP)

Correspondence Address: Michael A. Cantor, Esq.;CANTOR COLBURN LLP, 55 Griffin Road South, Bloomfield, CT, 06002, US

(21) Appl. No.: 11/142,224

(22) Filed: Jun. 1, 2005

Related U.S. Application Data
(62) Division of application No. 10/231,963, filed on Aug. 30, 2002.

(30) Foreign Application Priority Data
Aug. 31, 2001 (JP) 2001-264694

(51) Int. Cl. H01L 27/15

(52) U.S. Cl. 438/34

(57) ABSTRACT

An evaporation mask onto which an opening is formed for selectively allowing passage of an evaporation substance from an evaporation source onto a glass substrate to form an evaporation layer of an electroluminescence element in a predetermined pattern is placed between an evaporation source and a glass substrate and evaporation is performed. As a material for the evaporation mask, a material having a thermal expansion coefficient 160% or smaller of the thermal coefficient of glass is employed so as to minimize the thermal deformation of the evaporation mask which is closer the evaporation source and temperature of which is increased, to thereby improve the evaporation patterning precision.

### BACKGROUND OF THE INVENTION

1. Field of the Invention

The present invention relates to an evaporation process performed when an electroluminescence (EL) element is formed on a glass substrate.

2. Description of the Related Art

A type of EL display panel is known in which an organic EL element or the like is employed as an emissive element in each pixel. Expanding use of such an EL display panel as a self-illuminating flat panel is widely expected.

As an organic EL element, a structure is known, for example, in which an anode made of a transparent electrode such as ITO (Indium Tin Oxide) and a cathode made of a metal electrode such as Al or a magnesium alloy are layered on a glass substrate, with an organic layer including an emissive layer provided between the anode and cathode.

For manufacturing such an organic EL element, an evaporation method is employed for forming the organic layer and the metal electrode. During the evaporation, an evaporation mask in which openings are formed corresponding to a predetermined pattern desired for each layer is used. For example, because a material for an organic layer used in a low molecular weight organic EL element is vulnerable to moisture, it is not possible to employ a method, for example, in which an organic layer is first formed on the entire surface of the substrate and then the organic layer is etched and patterned into a predetermined shape. Therefore, a method is employed in which the region for evaporation is limited or defined in advance using an evaporation mask so that the organic layer is patterned at the same time as the evaporation.

The evaporation is performed by setting a substrate (glass substrate) which is the processing target within a vacuum chamber with the surface for evaporation facing downwards, placing an evaporation mask between the surface for evaporation of the substrate and an evaporation source, heating the evaporation source to vaporize the material to be evaporated, and adhering the evaporation material onto the substrate surface through the openings on the mask.

Typically, a nickel mask is used as the evaporation mask because methods for precisely and stably manufacturing a nickel mask are well established. More specifically, a method is well established in which a resist of a predetermined pattern is formed on a stainless base material or the like and a nickel mask is formed through electrodeposition. With this method, a precise mask can be stably manufactured. In addition, because the evaporation mask is placed relatively close to the evaporation source which is heated and the evaporation substance incoming to the mask is at a relatively high temperature, the evaporation mask must have a sufficient thermal endurance to endure the high temperature. A nickel mask satisfies this requirement of sufficient thermal endurance.

However, in practice, a problem has been found in that patterning with sufficient precision cannot be achieved when evaporation is performed using a nickel mask. After extensive experiment and study, the present inventors have found that this is caused by the thermal deformation of the nickel mask.

When the number of pixels on one substrate is small and, consequently, the light emission area per pixel is sufficiently large, as light position mismatch in the organic layer, in particular, in the formation region of the emissive layer, caused by slight deformation of the evaporation mask during evaporation does not significantly degrade the quality of the display device. However, in a high resolution display panel, because the area of each pixel is very small, the requirement of precision for patterning the organic layer is stricter, and thus, pattern mismatch of the organic layer caused by the mask deformation is a crucial problem. In addition, in a manufacturing process of a large-scale display panel or in a manufacturing process employing “gang printing” in which a plurality of display panels are formed using a large-area mother substrate, the area to be evaporated is large and a large-size mask is employed as the evaporation mask. When the area of the evaporation mask is increased, the problem of the position mismatch becomes more significant as thermal deformation occurs in the evaporation mask in addition to the increase in the amount of deformation due to the weight of the evaporation mask itself.

### SUMMARY OF THE INVENTION

Accordingly, an object of the present invention is to provide a method for manufacturing an EL display panel in which a precise patterning can be achieved during evaporation.

In order to achieve at least the object mentioned above, according to one aspect of the present invention, there is provided a method for manufacturing an EL display panel in which EL elements are provided on a glass substrate in a matrix form, wherein an evaporation mask made of a material having a thermal expansion coefficient within a range from 30% to 160% of the thermal expansion coefficient of the glass substrate is used when a material to be evaporated as an element is vaporized at an evaporation source and is evaporated onto the glass substrate to form an evaporation element layer of the EL element, and the evaporation mask is placed between the evaporation source and the glass substrate and the evaporation element layer is patterned at the same time as the evaporation of the material to be evaporated as an element.

According to another aspect of the present invention, there is provided an evaporation mask onto which one or more openings are formed for allowing selective passage of an evaporation substance from an evaporation source onto a glass substrate to form an evaporation element layer of an electroluminescence element in a predetermined pattern, the evaporation mask being placed between the evaporation source and the glass substrate when the evaporation element layer is formed on the glass substrate, wherein the evaporation mask is made of a material whose thermal expansion coefficient is within a range from 30% to 160% of the thermal expansion coefficient of the glass substrate.

According to yet another aspect of the present invention, it is preferable that the material for the evaporation mask is an alloy containing iron and nickel.

As described, by constructing an evaporation mask from a material whose thermal expansion coefficient is within a range from 30% to 160% of the glass used for the element substrate, it is possible to reduce the thermal deformation of the evaporation mask caused by heating by the evaporation source and to precisely pattern an evaporation element layer on a glass substrate. As a result, it is possible to obtain a high quality EL display panel.

According to another aspect of the present invention, there is provided a method for manufacturing an electroluminescence display panel in which electroluminescence elements are formed on a glass substrate in a matrix form, wherein an evaporation mask made of a material having a thermal expansion coefficient within a range from 30% to 160% of the thermal expansion coefficient of glass is used when a material to be evaporated as an element is vaporized at an evaporation source and is evaporated onto a glass substrate to form an evaporation element layer of an electroluminescence element, and the evaporation mask is placed between the evaporation source and the glass substrate using a mask supporting mechanism in which a material having a thermal expansion coefficient within a range from 30% to 160% of the thermal expansion coefficient of glass is used at least for a mask holding section, and the evaporation element layer is patterned simultaneously with the evaporation of the material to be evaporated as an element.

According to another aspect of the present invention, it is preferable that each of the materials for the evaporation mask and for the mask holding section is an alloy containing iron and nickel.

In this manner, similar to the evaporation mask, by using a material, for the mask holding section, having a thermal expansion coefficient similar to the glass substrate, that is, a thermal expansion coefficient similar also to the evaporation mask, it is possible to inhibit the thermal stress between the holding section and the evaporation mask even when the temperature of the holding section is increased during evaporation, and to prevent application of excessive stress to the evaporation mask.

According to another aspect of the present invention, there is provided a method for manufacturing an electroluminescence display panel in which electroluminescence elements are formed on a glass substrate in a matrix form, wherein when a material to be evaporated as an element is vaporized at an evaporation source and is evaporated onto a glass substrate to form an evaporation element layer of an electroluminescence element, an evaporation mask is placed between said evaporation source and said glass substrate using a mask supporting mechanism in which a material having a thermal expansion coefficient within a range from 30% to 160% of the thermal expansion coefficient of glass is used at least for a mask holding section, and said evaporation element layer is patterned simultaneously with the evaporation of said material to be evaporated as an element.

In this manner, by using a material, for the mask holding section, having a thermal expansion coefficient similar to the glass substrate, that is, a material having a thermal expansion smaller than the conventional nickel mask, etc., it is possible to easily maintain supporting function of the evaporation mask even when the temperature of the holding section is increased by, for example, thermal conduction, because of the smaller degree of thermal deformation.

### BRIEF DESCRIPTION OF THE DRAWINGS

FIG. 1 is a diagram for explaining the evaporation process according to a preferred embodiment of the present invention.

FIG. 2 is a planer diagram showing an example of a planer structure of an evaporation mask according to a preferred embodiment of the present invention.

FIG. 3 is a diagram showing a circuit structure around each pixel in an organic EL display panel manufactured through the method of manufacturing according to a preferred embodiment of the present invention.

FIG. 4 is a diagram showing a partial cross sectional structure of a pixel in an organic EL display panel manufactured through a method according to a preferred embodiment of the present invention.

### DESCRIPTION OF PREFERRED EMBODIMENT

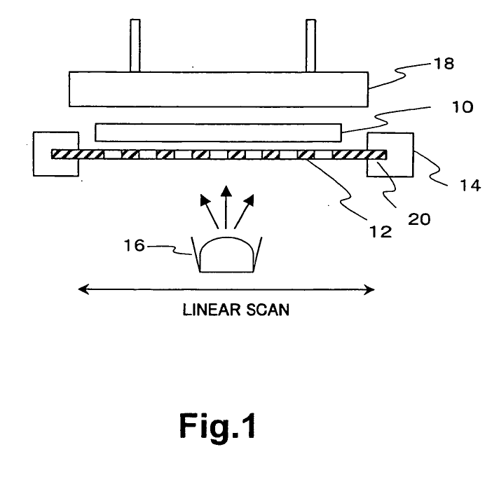

A preferred embodiment of the present invention (hereinafter simply referred to simply as “the embodiment”) will now be described referring to the drawings. FIG. 1 is a diagram for explaining an evaporation process for an organic layer or the like of an organic EL panel according to the embodiment.

A glass substrate 10 for an EL panel is placed within an evaporation chamber of a vacuum evaporation device with its surface for evaporation facing downward. An evaporation mask 12 which is larger than the glass substrate 10 is placed below the glass substrate 10. In FIG. 1, the glass substrate 10 and the evaporation mask 12 are shown to be distanced from each other, but, in practice, the glass substrate 10 and the evaporation mask 12 are in contact with each other over almost the entire surface with no gap formed in between. The ends of the evaporation mask 12 are supported by a supporting mechanism 14.

Below the evaporation mask 12, an evaporation source 16 is placed for heating an evaporation material (for example, to a temperature of approximately 300° C.). In this example, the evaporation source 16 is a linear-shaped evaporation source 16 elongated in the direction into the page and is moveable in the right and left direction of the page and into and out of the page. Evaporation is performed by moving the evaporation source 16 while heating and vaporizing the material.

Above the glass substrate 10, a magnet 18 is provided so that the evaporation mask 12 made of a magnetic material as will be described below can be attracted in order to prevent flexure of the central portion of the mask 12 toward the downward direction due to its own weight.

With such a device, a specific evaporation material is set in the evaporation source 16, a corresponding mask 12 is placed between the evaporation source 16 and the glass substrate 10, and the evaporation source 16 is scanned. In this manner, the evaporation substance adheres onto the entire surface of the glass substrate 10 through the openings on the evaporation mask 12, and an evaporation layer such as the organic layer is formed at predetermined positions on the substrate 10 corresponding to the pattern of the openings. In other words, by employing such an evaporation mask 12, the evaporation layer is patterned during the evaporation process.

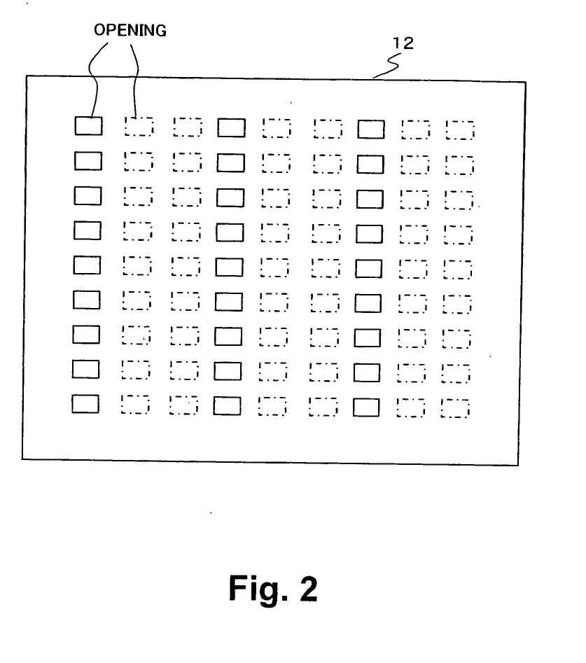

FIG. 2 shows an example planer structure of an evaporation mask 12 which is an example mask for forming an organic layer such as the emissive layer of the organic EL element. The structure of the organic EL element will be described later. On the mask 12, openings are formed only in the positions corresponding to the light emitting regions of the same color among the light emitting regions of R, G, and B organic EL elements which are placed in a matrix form on a glass substrate. The mask 12 can be used for forming organic EL elements using different organic emissive materials for R, G, and B. When an organic layer or an emissive layer of one color is formed, the mask 12 is placed below the glass substrate 10 as shown in FIG. 1 and evaporation is performed. Then, the evaporation material in the evaporation source 16 is changed, and the evaporation mask 12 is replaced with another evaporation mask for another color, or, alternatively, the same evaporation mask is moved so that the mask openings are at positions shown by a one dotted chain line in FIG. 1 relative to the glass substrate 10. Then, the organic layers for other colors are sequentially formed through evaporation.

In the present embodiment, a material whose thermal expansion coefficient is similar to or less than the thermal expansion coefficient of glass which in turn has a thermal expansion coefficient of approximately ⅓ of the thermal expansion coefficient of pure Ni is used as the material for the evaporation mask 12 as described above. An example material is an alloy containing iron and nickel and whose thermal expansion coefficient is close to or less than the thermal expansion coefficient of glass.

More specifically, materials such as, for example, (i) 42ALLOY which is an alloy of Fe and 42% Ni with a thermal expansion coefficient of 35×10⁻⁷/K (K: Kelvin)−55×10⁻⁷/K, (ii) an Inver material which is an alloy of Fe and 36% Ni with a thermal expansion coefficient of 17.5×10⁻⁷/K and (iii) a super Inver material which is an alloy of Fe, 31% Ni, and 5% Co with a thermal expansion coefficient of 6.9×10⁻⁷/K can be used.

The thermal expansion coefficient of glass is approximately 38×10⁻⁷ and the thermal expansion coefficient of nickel which is conventionally used as a material for the mask is approximately 130×10⁻⁷. It can therefore be seen that the above materials have thermal expansion coefficients which are similar to that of the glass used for the substrate. By forming the mask 12 from these materials, it is possible to obtain thermal expansion of mask 12 during the evaporation which is similar to the thermal expansion of glass substrate 10. Because of this, the deformation of the glass substrate 10 and the deformation of the mask 12 can be cancelled out and the influence of the increase in temperature can be eliminated, to thereby allow precise patterning.

In addition, because the evaporation mask is placed closer to the high temperature evaporation source 16 than the glass substrate 10 which is the evaporation target, the temperature of the mask 12 becomes approximately 10° C. to 30° C. higher than the temperature of the glass substrate 10, although the specific difference in temperature varies depending on the distance from the evaporation source 16. Therefore, by using a material having a thermal expansion coefficient less than that of the glass for the evaporation mask 12, it is possible to further reduce the thermal deformation of the mask 12 to thereby improve the precision of patterning.

An example case where Ni is used for the evaporation mask will now be described. When the temperature of the evaporation mask 12 and the glass substrate 10 having a width of 400 mm is increased by 10° C. during the evaporation, the difference in thermal deformation is
(130−38)×10⁻⁷×10° C.=9.2×10⁻⁵
where the thermal expansion coefficient of glass is 38×10⁻⁷ and the thermal expansion coefficient of Ni is 130×10⁻⁷. Therefore, a mismatch of 36 μm is created (400 mm×9.2×10⁻⁵=36 μm).

For practical purposes, the positional mismatch between the glass substrate 10 and the evaporation mask 12 caused by the thermal expansion must be inhibited to 10 μm or less. Therefore, for a glass substrate and an evaporation mask of 400 mm width, it is desirable that the thermal expansion coefficient be in the range from 60×10⁻⁷/K (which is 157% of the thermal expansion coefficient of glass) to 13×10⁻⁷/K (which is 34% of the thermal expansion coefficient of glass).

In other words, it is desirable that the thermal expansion coefficient of the evaporation mask be within a range of 30%-160% of that of the glass. By employing a material having a thermal expansion coefficient satisfying such a condition for the evaporation mask, it is possible to prevent significantly differing thermal deformation between the glass substrate 10 and the evaporation mask 12 during evaporation, and thus, it is possible to precisely evaporate the organic layer, etc. onto the glass substrate.

When the thickness of the evaporation mask 12 is too large, evaporation substance incoming at an angled direction from the evaporation source 16 may not be able to pass through the mask openings, and, thus, the evaporation efficiency and precision may be degraded. For this reason, the thickness of the evaporation mask 12 is designed in a range of 10 μm to 100 μm, which is relatively very thin compared to the thickness of the glass substrate 10 which is approximately 0.7 mm. Therefore, the material for the mask must have sufficient strength even when formed in such a thin state. The above-described materials satisfy this condition. Moreover, because the above-described materials are magnetic, these materials are desirable as the flexure around the central portion of the mask toward the downward direction can be alleviated using the magnet 18 as shown in FIG. 1. When a material having relatively small stiffness is employed instead of a magnetic material as the material for the mask, it is possible to prevent the flexure of the mask 12 due to its own weight using an electrostatic suctioning mechanism in place of the magnet 18 shown in FIG. 1.

Although in the above example, an alloy containing iron and nickel is employed as the material for the mask 12, the material for the mask 12 is not limited to the above-described materials as long as a material having a thermal expansion coefficient similar to or less than that of the glass and a sufficient thermal endurance is used for the mask. For example, it is also preferable to employ glass to form the mask 12. With such a configuration, it is possible to set the thermal expansion coefficients of the glass substrate 10 and of the mask 12 to be substantially identical and to practice precise patterning.

It is desirable that the mask supporting mechanism (mask frame) 14 be constructed such that, for example, when the supporting mechanism is configured to hold the ends of the evaporation mask 12, at least the mask holding section 20 is made of a material whose thermal expansion coefficient is similar to that of the evaporation mask 12. In other words, it is desirable to use a mask supporting mechanism 14 in which a material having a thermal expansion coefficient within a range from 30% to 160% of that of the glass substrate is used for the mask holding section 20, such as, for example, 42ALLOY (having a thermal expansion coefficient of 35×10⁻⁷/K−55×10−⁻⁷/K), an Inver material (having a thermal expansion coefficient of 17.5×10⁻⁷/K), and a super Invar material (having a thermal expansion coefficient of 6.9×10⁻⁷/K) as described above. By using such a material, it is possible to prevent application of excessive stress to the evaporation mask 12 when the temperature of the holding section is increased by, for example, heat conduction. Also, regardless of the material for the evaporation mask, by using a material having a thermal expansion coefficient within a range from 30% to 160% of that of the glass substrate for the mask holding section 20 of the mask supporting mechanism 14, it is possible to reliably support the mask because the deformation is smaller compared to the conventional materials such as Ni having a high thermal expansion coefficient and the holding strength of the evaporation mask 12 tends not be weakened even at high temperatures.

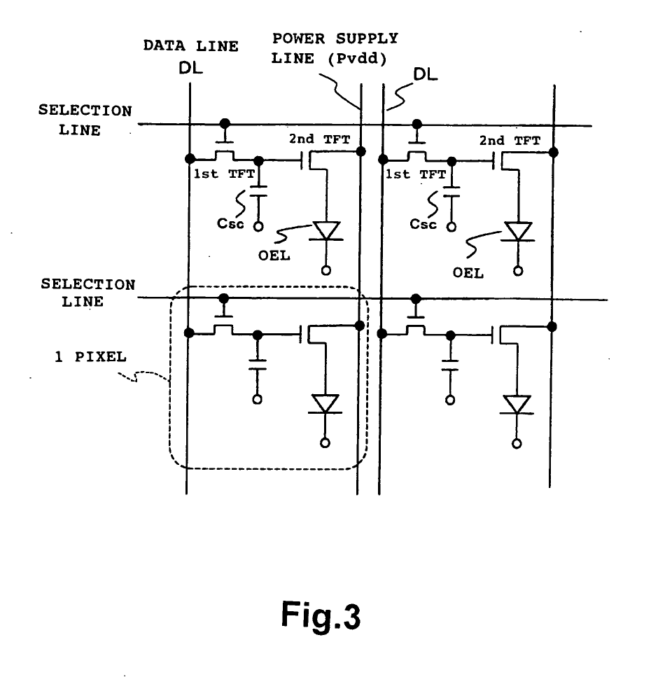

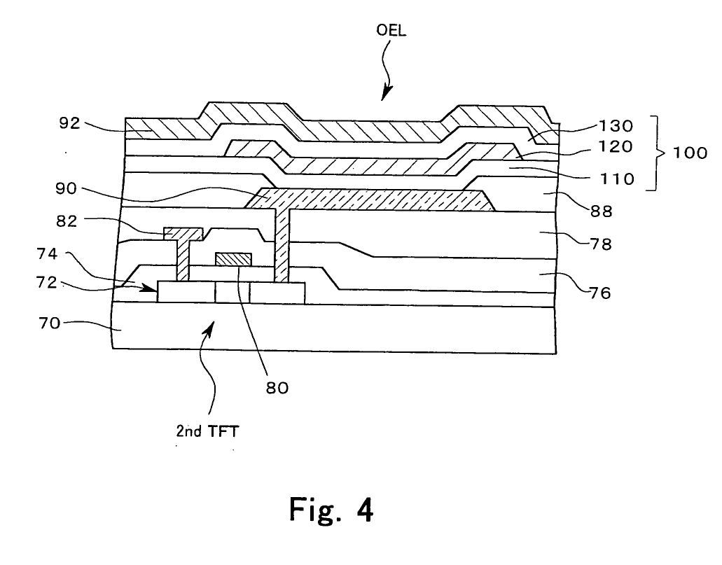

FIG. 3 shows an example equivalent circuit around a pixel of an organic EL display panel formed through the evaporation method as described. As shown in FIG. 3, each pixel comprises a first TFT, a second TFT, a storage capacitor Csc, and an organic EL element. FIG. 4 shows a cross sectional structure of the second TFT and the organic EL element in each pixel in an organic EL display panel.

The gate electrode of the first TFT is connected to the selection (scan) line and the TFT is switched on in response to the selection signal. When the first TFT is switched on, charges output on the data line at that point of time and corresponding to the display data are accumulated in the storage capacitor Csc through the source and drain of the first TFT. One of the source and the drain of the second TFT is connected to a power supply line 82 and the other of the source and the drain is connected to the anode 90 of the organic EL element. The gate electrode 80 of the second TFT is connected to the storage capacitor Csc and the source and drain of the second TFT are connected between the power supply (Pvdd) line and the anode (first electrode) of the organic EL element. The second TFT supplies electric current from the power supply to the anode of the organic EL element in response to the voltage applied on the gate by the storage capacitor Csc. The organic EL element has a cross sectional shape as shown in FIG. 4 and has a structure wherein an organic layer 100 including an emissive layer is formed between the first electrode 90 and the second electrode 92.

The second TFT for driving the organic EL element and the first TFT (not shown in FIG. 4) have structures that are similar to each other and the second TFT comprises an active layer 72 formed over a transparent substrate 70 such as glass and made of polycrystalline silicon (poly Si) which is polycrystallized by laser annealing, a gate insulative film 74 covering the active layer 72, and a gate electrode 80. One of the source and the drain of the second TFT is connected to a power supply line 82 through a contact hole formed to penetrate through an interlayer insulative film 76 and the gate insulative film 74 formed to cover the entire TFT. A first planarizing insulative film 78 is formed over the entire surface of the substrate covering the power supply line 82. The first electrode 90 made of ITO is formed on the first planarizing insulative film 78 and patterned into individual patterns for each pixel through etching. The first electrode 90 is connected to the other of the source or the drain of the second TFT through a contact hole formed to penetrate through the first planarizing insulative film 78, the interlayer insulative film 76, and the gate insulative film 74.

The organic EL element is formed on the planarizing insulative film 78 after the second TFT for driving the organic EL element, the first TFT (not shown in FIG. 4), and the storage capacitor are formed over the glass substrate 70 and the planarizing insulative film 78 is formed. The first electrode 90 of the organic EL element is a transparent electrode made of an ITO or the like and functions as the anode. The second electrode 92 is a metal electrode made of, for example, aluminum or an aluminum alloy and functions as the cathode. The organic layer 100 comprises, for example, a hole transport layer 110, an emissive layer 120, and an electron transport layer 130, layered in that order from the first electrode 90. Among these layers forming the organic EL element, the organic layer 100 and the second electrode 92 are formed through evaporation. In the example shown in FIG. 4, among the layers forming the organic layer 100, the emissive layer 120 has an independent pattern for each pixel similar to the first electrode 90 (although each emissive layer 120 is slightly larger than the corresponding first electrode 90) and each of the hole transport layer 110 and electron transport layer 130 has a pattern common to all pixels. The second electrode 92 which is a cathode also has a pattern common to all pixels. For the emissive layer 120 of the organic layer 100, independent pattern for each pixel is obtained at the same time as the evaporation by first forming a hole transport layer 110 over almost the entire surface of the substrate through evaporation, placing, in front of the substrate, an evaporation mask 12 having openings only in positions corresponding to the light emitting region of elements of the same color as shown in FIG. 2, and vaporizing a corresponding light emitting material at the evaporation source 16. As the evaporation mask 12, because a mask made of an material having a thermal expansion coefficient similar to, or less than, that of the glass is used, the deformation during the evaporation can be reduced, and, in the example shown in FIG. 4, substantially no mismatch between the formation region of the emissive layer 120 and the corresponding formation region of the first electrode 90 is created and precise patterning can be effected. When it is desired that the hole transport layer 110 and/or the electron transport layer 130 also have an individual pattern for each pixel similar to the emissive layer 120, an evaporation mask 12 can be employed which has an opening pattern similar to that for the emissive layer 120 as shown in FIG. 2 and which is made of a material whose thermal expansion coefficient is as described above.

In an active matrix type organic EL panel comprising an organic EL element and a switch for driving the organic EL element in each pixel, when display data is supplied to each pixel via a data line DL, a voltage corresponding to the data is applied to the gate of the second TFT via the first TFT and the storage capacitor Csc and an electric current corresponding to the display data is supplied to the first electrode 90 of the organic EL element from a power supply Pvdd. Then, holes are injected from the first electrode 90 through the hole transport layer 110 and electrons are injected from the second electrode 92 through the electron transport layer 130 into the emissive layer 120 where recombination of the holes and electrons occurs so that the organic light emitting molecule is exited. As the excited light emitting molecule returns to its ground state, light of a color intrinsic to the light emitting molecule is emitted. In an organic EL element, because light is emitted from the organic layer provided in the region between the first electrode 90 and the second electrode 92, by forming the organic layer of the organic EL element at precise positions relative to the first electrode 90 using the evaporation mask 12 according to the present embodiment, it is possible to achieve uniform light emission area and light emission brightness among the pixels in a panel.

1-8. (canceled)

9. A method for manufacturing an electroluminescence display panel in which electroluminescence elements are formed on a glass substrate in a matrix form, wherein
an evaporation mask made of a material having a thermal expansion coefficient of approximately 18.16% of a thermal expansion coefficient of glass is used when a material to be evaporated as an element is vaporized at an evaporation source and is evaporated onto a glass substrate to form an evaporation element layer of an electroluminescence element; and
said evaporation mask is placed between said evaporation source and said glass substrate and said evaporation element layer is patterned simultaneously with evaporation of said material to be evaporated as an element.

10. A method for manufacturing an electroluminescence display panel according to claim 9, wherein said material for said evaporation mask is an alloy of iron (Fe), nickel (Ni) in an amount of 31% of said iron, and cobalt (Co) in an amount of 5% of said iron.

11. A method for manufacturing an electroluminescence display panel in which electroluminescence elements are formed on a glass substrate in a matrix form, wherein
an evaporation mask made of a material having a thermal expansion coefficient of approximately 18.16% of a thermal expansion coefficient of glass is used when a material to be evaporated as an element is vaporized at an evaporation source and is evaporated onto a glass substrate to form an evaporation element layer of an electroluminescence element; and
said evaporation mask is placed between said evaporation source and said glass substrate using a mask supporting mechanism in which a material having a thermal expansion coefficient of approximately 18.16% of said thermal expansion coefficient of glass is used at least for a mask holding section, and said evaporation element layer is patterned simultaneously with evaporation of said material to be evaporated as an element.

12. A method for manufacturing an electroluminescence display panel according to claim 11, wherein each of said materials for said evaporation mask and for said mask holding section is an alloy of iron (Fe), nickel (Ni) in an amount of 31% of said iron, and cobalt (Co) in an amount of 5% of said iron.

13. A method for manufacturing an electroluminescence display panel in which electroluminescence elements are formed on a glass substrate in a matrix form, wherein
when a material to be evaporated as an element is vaporized at an evaporation source and is evaporated onto a glass substrate to form an evaporation element layer of an electroluminescence element, an evaporation mask is placed between said evaporation in which a material having a thermal expansion coefficient of approximately 18.16% of said thermal expansion coefficient of glass is used at least for a mask holding section, and said evaporation element layer is patterned simultaneously with evaporation of said material to be evaporated as an element.

14. A method for manufacturing an electroluminescence display panel according to claim 13, wherein said material for said mask holding section is an alloy of iron (Fe), nickel (Ni) in an amount of 31% of said iron, and cobalt (Co) in an amount of 5% of said iron.
